(19) United States
(12) Patent Application Publication
(10) Pub. No.: US 2025/0259950 A1
(43) Pub. Date: Aug. 14, 2025

(54) SEMICONDUCTOR DEVICE WITH MULTIPLE PASSIVATION MATERIALS AT A BONDING SURFACE

(71) Applicant: Micron Technology, Inc., Boise, ID (US)

(72) Inventor: Wei Zhou, Boise, ID (US)

(21) Appl. No.: 19/017,227

(22) Filed: Jan. 10, 2025

Related U.S. Application Data
(60) Provisional application No. 63/553,430, filed on Feb. 14, 2024.

(51) Int. Cl. H01L 23/00; H01L 23/48; H01L 23/544; H01L 25/065; H10B 80/00; H10D 80/30

(52) U.S. Cl. CPC H01L 24/05; H01L 23/544; H01L 24/06; H01L 24/08; H01L 24/80; H01L 24/96; H01L 24/97; H01L 25/0652; H01L 23/481; H01L 24/16; H01L 24/32; H01L 24/73; H01L 2223/5446; H01L 2224/05687; H01L 2224/06505; H01L 2224/08145; H01L 2224/16225; H01L 2224/32225; H01L 2224/73204; H01L 2224/80895; H01L 2224/80896; H01L 2224/96; H01L 2224/97; H01L 2924/3656; H10B 80/00; H10D 80/30

(57) ABSTRACT

A semiconductor device assembly is disclosed. The semiconductor device assembly includes a semiconductor substrate having a plurality of die locations at which a plurality of semiconductor dies are implemented, a scribe area interleaved between the plurality of die locations, and a peripheral area near a periphery of the semiconductor substrate. A first passivation material is disposed at the plurality of die locations, and a second passivation material is disposed at the scribe area and the peripheral area. The first passivation material and the second passivation material implement a bonding surface of the semiconductor device assembly.

### CROSS-REFERENCE TO RELATED APPLICATION(S)

The present application claims priority to U.S. Provisional Patent Application No. 63/553,430, filed Feb. 14, 2024, the disclosure of which is incorporated herein by reference in its entirety.

### TECHNICAL FIELD

The present disclosure generally relates to semiconductor device assembly and more particularly relates to a semiconductor device with multiple passivation materials at a bonding surface.

### BACKGROUND

Wafer bonding is a wafer-level packaging technology that can be used to form semiconductor device assemblies. During wafer bonding, the two semiconductor wafers can be brought into contact with one another at their respective bonding surfaces. Interconnects can be formed between the wafers. Similarly, the dielectric material at each respective wafer can bond to mechanically couple the two semiconductor wafers. During bonding, moisture can be trapped at the bond line between two wafers and create voids. These voids can reduce the bond strength between the two semiconductor wafers or, in some cases, disconnect interconnects between the wafers, which can render the semiconductor devices implemented thereon inoperable.

### BRIEF DESCRIPTION OF THE DRAWINGS

FIG. 1 illustrates a simplified schematic cross-sectional view of a semiconductor device assembly that includes a semiconductor substrate with multiple passivation materials in accordance with an embodiment of the present technology.

FIG. 2 illustrates a simplified schematic partial plan view of a semiconductor substrate with multiple passivation materials in accordance with an embodiment of the present technology.

FIGS. 3-9 illustrate simplified schematic cross-sectional views of a series of operations for assembling a semiconductor device in accordance with an embodiment of the present technology.

FIG. 10 illustrates a schematic view of a system that includes a semiconductor device in accordance with an embodiment of the present technology.

FIG. 11 illustrates a method for assembling a semiconductor device in accordance with an embodiment of the present technology.

### DETAILED DESCRIPTION

Semiconductor devices are integrated into many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. Improvements in packaging have enabled multiple semiconductor dies to be assembled into a single package to implement a single packaged device with increased functionality. To implement this improved device with limited increase to the package footprint, semiconductor dies can be stacked onto one another.

Often, to form stacked semiconductor devices, two semiconductor wafers, each implementing multiple dies, can be bonded such that the respective dies on each of the wafers couple with one another. The bonding process can include forming interconnects between contacts at the respective semiconductor dies on each wafer and bonding passivation layers (e.g., of dielectric material) at respective bonding surfaces of the wafers. Generally, the bonding process must be controlled to ensure that the wafers are free of contaminants that, when present on the bonding surfaces, can create voids (e.g., portions of the bonding surfaces of the wafers that are unbonded). If the voids are large enough, they can weaken the bond between the semiconductor wafers to the point of failure or separate and short out interconnects between bonded semiconductor dies, rendering these dies inoperable.

Limiting contamination at the bonding surface can be very difficult, in part because various steps of the bonding process can create contaminants. For example, the bonding process can include hydrating the bonding surfaces of the semiconductor wafers and contacting the wafers in a high-temperature or high-pressure environment. The wafers can bond along a bond wave that propagates from the center of the wafers to the edges. As the bond wave propagates, moisture can be pushed toward the edges of the wafers where there is a drop in pressure. As a result, the moisture can condense at the edges of the wafers, and this condensation can create voids along the bonding interface.

Moreover, contaminants can be created as a result of fusion bonding the semiconductor wafers. In some cases, the fusion bond between the passivation layers of the wafers can produce moisture that can accumulate at the bonding surfaces. As a specific example, fusion bonding between Si—OH at the passivation layers of the wafers can produce moisture at the bonding surfaces. If the moisture cannot be diffused through the passivation layer, it can form voids between wafers.

To address these problems and others, the embodiments of the present technology provide a semiconductor substrate with multiple passivation materials implemented at a bonding surface. For example, a portion of the bonding surface can be implemented using a passivation material that has a high bonding energy such that bonds formed with a like material have a higher bonding strength. As a result, the higher bonding strength can reduce the occurrence of voids due to separation of semiconductor substrates at a bonding interface. On the other hand, this passivation material can be inconsistent with passivation material used for other assembly processes (e.g., passivation material used to insulate vias). This inconsistency can reduce the predictability and yield of the assembly process. Accordingly, some areas on the bonding surface can benefit from being implemented with a certain passivation material, even if that passivation material has a lower bonding strength.

The present technology leverages the benefits of both passivation materials by implementing a first passivation material (e.g., a passivation material consistent with other passivation materials used during assembly) in an active area of the semiconductor substrate in which semiconductor dies are implemented (e.g., a plurality of die locations) and a second passivation material in scribe areas and other undeveloped areas on the semiconductor substrate. As a result, the active areas, where the passivation material used to fabricate and assemble the semiconductor dies is present, can include a consistent passivation material, thereby improving yield. Moreover, the second passivation material can be used to form stronger bonds outside of the active area and in some of the locations where voids are most likely to occur (e.g., at the edge of the substrate), thereby reducing the occurrence of voids without creating inconsistencies with other passivation materials at the active area. Thus, the present technology enables the implementation of an improved semiconductor device with increased yield.

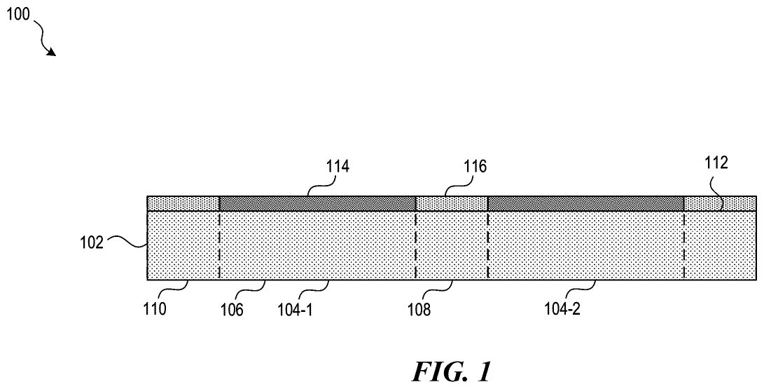

FIG. 1 illustrates a simplified schematic cross-sectional view of a semiconductor device assembly 100 that includes a semiconductor substrate 102 with multiple passivation materials in accordance with an embodiment of the present technology. The semiconductor substrate 102 can include a wafer-, strip-, or panel-level substrate. The semiconductor substrate 102 can include a semiconductor material, such as silicon, germanium, silicon-germanium alloy, gallium arsenide, gallium nitride, etc. In some cases, the semiconductor substrate may be a silicon-on-insulator (SOI) substrate, such as silicon-on-glass (SOG) or silicon-on-sapphire (SOP), or epitaxial layers of semiconductor materials on another substrate.

Multiple semiconductor dies 104 are implemented at the semiconductor substrate 102. The semiconductor substrate 102 can be attached to a carrier substrate (e.g., wafer). As illustrated, the semiconductor substrate 102 implements semiconductor die 104-1 and semiconductor die 104-2 (referred to generally as semiconductor dies 104). The semiconductor dies 104 can be of any type. For example, the semiconductor dies can be memory dies, such as dynamic random-access memory (DRAM) dies, NOT-AND (NAND) dies, or the like. Alternatively or additionally, the semiconductor dies 104 can include logic dies. The semiconductor dies 104 can be implemented at different lateral locations of the semiconductor substrate 102. The semiconductor dies 104 include transistors, capacitors, resistors, and other circuitry (not shown) connected with a back end of line layer (not shown). The back end of line layer can include traces, lines, vias, and other connective circuitry that provides connectivity to the semiconductor dies 104.

The semiconductor substrate 102 includes an active area 106 (e.g., a plurality of die locations), a scribe area 108, and a peripheral area 110. The semiconductor dies 104 are implemented at the active area 106. The scribe area 108 is located outside the active area 106 between the semiconductor dies 104. For example, the scribe area 108 can be interleaved between the plurality of die locations. In this way, the scribe area 108 can provide locations at which the semiconductor substrate 102 can be sawed to singulate the semiconductor dies 104. The peripheral area 110 is similarly located outside the active area 106. The peripheral area 110 can correspond to the periphery of the semiconductor substrate 102 (e.g., near the substrate edge) and surround the semiconductor dies 104.

A passivation layer can be disposed over the back end of line layer at a surface 112 (e.g., a front side) of the semiconductor substrate 102. The passivation layer can insulate the circuitry disposed at the semiconductor substrate 102 and provide a bonding surface for additional semiconductor dies. For example, the passivation layer can be used to form a hybrid or fusion bond with a passivation layer of an additional semiconductor device. Thus, in some cases, contact pads can be disposed in the passivation layer to implement interconnects between bonded semiconductor dies. Alternatively or additionally, the passivation layer can be a continuous layer, and the interconnects can be implemented between bonded semiconductor dies by drilling through the passivation layer directly to a back end of line layer.

The passivation layer can include multiple passivation materials (e.g., dielectric materials, such as silicon oxide, silicon nitride, silicon carbide, silicon carbon nitride, silicon oxide carbon, and so on). As illustrated, a passivation material 114 is disposed at the active area 106, and a passivation material 116 is disposed at the scribe area 108 and the peripheral area 110. For example, a lateral location of the passivation material 114 corresponds to a lateral location of the active area 106, and a lateral location of the passivation material 116 corresponds to a lateral location of the scribe area 108 and the peripheral area 110. In this way, the passivation material 114 can be vertically aligned with the active area 106, and the passivation material 116 can be vertically aligned with the scribe area 108 and the peripheral area 110. For example, the perimeter of the passivation material 114 can be vertically aligned with the perimeter of the active area 104 (e.g., at each of the die locations), and the passivation material 116 can be vertically aligned with the perimeter of the scribe area 108 and the peripheral area 110. In this way, the passivation material 114 can extend across the active area 106, and the passivation material 116 can extend from beyond the perimeter of the semiconductor dies 104. In some embodiments, the active area 106, the scribe area 108, or the peripheral area 110 can include multiple passivation materials (e.g., the same as or different from the passivation material 114 and the passivation material 116). The passivation material 114 and the passivation material 116 can be different passivation materials.

In aspects, the passivation material 116 has a higher bonding energy than the passivation material 114. In this way, a bond formed between the passivation material 116 and the same material can have a higher bonding strength than a bond formed between the passivation material 114 and the same material. In this way, the occurrence of voids at the passivation material 116 can be limited. The passivation material 114 can correspond to an insulating material used in other assembly processes. For example, the passivation material 114 can correspond to a passivation material used to insulate vias extending between bonded semiconductor dies. Thus, the passivation material 114 can be implemented at the active area to provide continuity with passivation material used to insulate vias, which are present at the active areas. As a specific example, the passivation material 114 includes silicon oxide, silicon oxide carbon, or any other dielectric, and the passivation material 116 includes silicon carbon nitride, a dielectric material deposited through a high aspect ratio process (HARP dielectric), or any other dielectric.

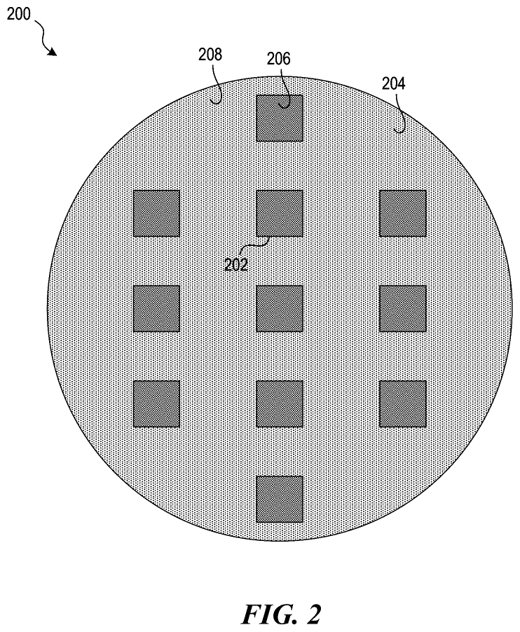

FIG. 2 illustrates a simplified schematic partial plan view of a semiconductor substrate 200 with multiple passivation materials in accordance with an embodiment of the present technology. The semiconductor substrate 200 includes semiconductor dies 202 implemented at different lateral locations of the semiconductor substrate 200. The semiconductor dies 202 can be spaced apart from one another to enable the semiconductor dies 202 to be singulated from one another through sawing at scribe areas between them. A bonding surface 204 at which additional semiconductor devices can be attached to the semiconductor substrate 200 is illustrated in FIG. 2. A passivation layer is disposed at the semiconductor substrate 200 to implement the bonding surface 204. The passivation layer includes a passivation material 206 in locations that correspond to the semiconductor dies 202 (e.g., in active areas) and a passivation material 208 in locations that are outside the semiconductor dies 202 (e.g., in scribe areas and peripheral areas).

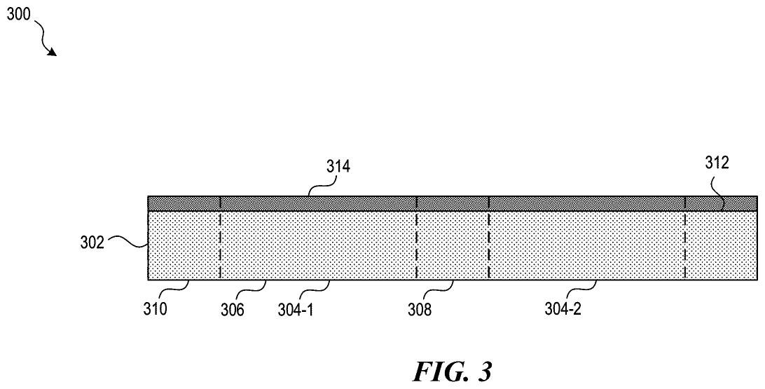

This disclosure now turns to a series of steps for fabricating semiconductor device assemblies in accordance with embodiments of the present technology. Specifically, FIGS. 3-9 illustrate simplified schematic cross-sectional views of a series of operations for assembling a semiconductor device in accordance with embodiments of the present technology. The operations are illustrated with respect to specific embodiments for ease of description. However, the operations described with respect to FIGS. 3-9 could be performed to assemble semiconductor devices in accordance with other embodiments.

Beginning with FIG. 3 at stage 300, a semiconductor substrate 302 including semiconductor die 304-1 and semiconductor die 304-2 (referred to collectively as semiconductor dies 304) is provided. The semiconductor substrate 302 includes an active area 306 at which the semiconductor dies 304 are implemented, a scribe area 308 between the semiconductor dies 304, and a peripheral area 310 surrounding the semiconductor dies 304. The active area 306, the scribe area 308, and the peripheral area 310 make up different portions of a surface 312 (e.g., a front side) of the semiconductor substrate 302.

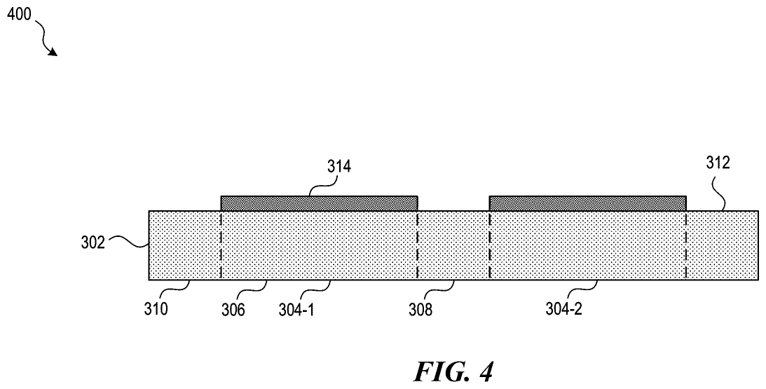

A passivation material 314 is disposed at the surface 312 of the semiconductor substrate 302 through any number of techniques, such as chemical vapor deposition (CVD), physical vapor deposition (PVD), dispensing, oxidation, spin coating, and/or other suitable techniques. The passivation material 314 can include a dielectric material, such as silicon oxide, silicon nitride, silicon carbide, silicon carbon nitride, silicon oxide carbon, and so on. The passivation material 314 can correspond to a dielectric material used to insulate circuitry formed during other assembly processes. As a specific example, the passivation material 314 can include silicon oxide or silicon oxide carbon. The passivation material 314 can be disposed across the entire surface 312 (e.g., at the active area 306, the scribe area 308, and the peripheral area 310). Portions of the passivation material 314 can then be removed to implement the passivation material 314 at only portions of the surface 312, as illustrated in FIG. 4.

Turning next to FIG. 4 at stage 400, portions of the passivation material 314 are removed to expose the semiconductor substrate 302. The passivation material 314 can be removed at the scribe area 308 and the peripheral area 310. As a result, the passivation material 314 can be disposed only at the active area 306, which corresponds to the semiconductor dies 304. The portions of passivation material 314 that correspond to the scribe area 308 and the peripheral area 310 can be removed through any number of techniques, such as using plasma etching, wet etching, chemical-mechanical planarization (CMP), drilling, or other suitable techniques. Although illustrated in two operations in which the passivation material 314 is disposed over the entire surface 312 of the semiconductor substrate 302 and then selectively removed, in other embodiments, the passivation material 314 can be selectively disposed in locations that correspond to the active area 306.

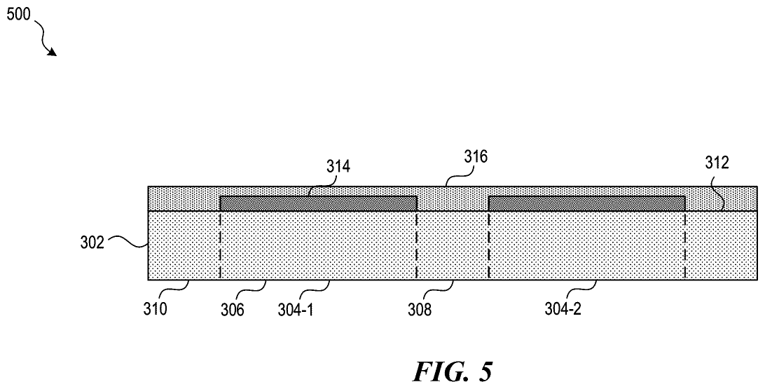

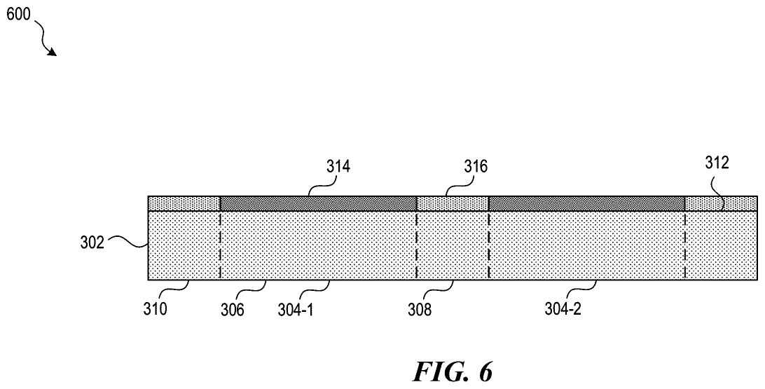

Turning next to FIG. 5 at stage 500, a passivation material 316 is disposed at the surface 312 of the semiconductor substrate 302 and over the passivation material 314 through any number of techniques, such as CVD, PVD, dispensing, oxidation, spin coating, and/or other suitable techniques. The passivation material 316 can include a dielectric material, such as silicon oxide, silicon nitride, silicon carbide, silicon carbon nitride, silicon oxide carbon, and so on. The passivation material 316 can correspond to a dielectric material with a high bond energy. As a specific example, the passivation material 316 can include silicon carbon nitride or a HARP dielectric. The passivation material 316 can have a higher bonding energy than the passivation material 314. The passivation material 316 can be disposed over the surface 312 (e.g., at the active area 306, the scribe area 308, and the peripheral area 310) and the passivation material 314. Portions of the passivation material 316 can then be removed to expose the passivation material 314 and the remaining passivation material 316 at a bonding surface, as illustrated in FIG. 6.

Turning next to FIG. 6 at stage 600, the portions of the passivation material 316 are removed to expose the passivation material 314 and the remaining passivation material 316. For example, the passivation material 316 disposed over the passivation material 314 can be removed to expose the passivation material 314 at the active area 306, which corresponds to the semiconductor dies 304, and expose the passivation material 316 at the scribe area 308 and the peripheral area 310. The passivation material 316 can be removed through any number of techniques, such as using plasma etching, wet etching, CMP, drilling, or other suitable techniques. In some cases, the passivation material 316 is removed through CMP. In aspects, the CMP can remove a portion of the passivation material 314 to form a planar bonding surface implemented using the passivation material 314 and the passivation material 316. Although illustrated in two operations in which the passivation material 316 is disposed over the surface 312 of the semiconductor substrate 302 and the passivation material 314 and then selectively removed, in other embodiments, the passivation material 316 can be selectively disposed in locations that correspond to the scribe area 308 and the peripheral area 310.

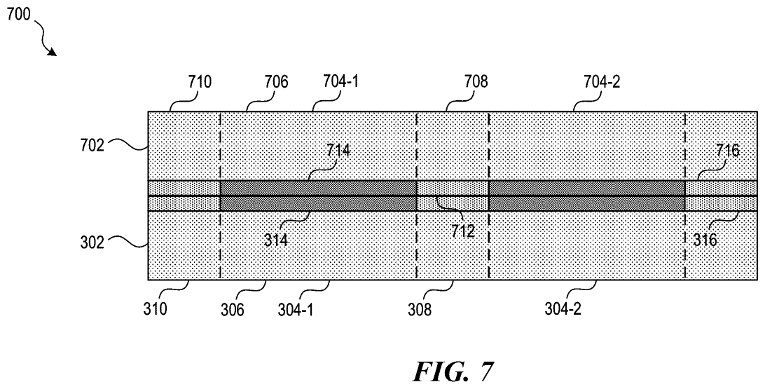

Turning next to FIG. 7 at stage 700, the semiconductor substrate 302 is bonded with a semiconductor substrate 702. The semiconductor substrate 702 can be implemented similar to the semiconductor substrate 302. For example, the semiconductor substrate 702 includes semiconductor die 704-1 and semiconductor die 704-2 (referred to collectively as semiconductor dies 704) implemented at an active area 706, a scribe area 708 between the semiconductor dies 704, and a peripheral area 710 surrounding the semiconductor dies 704.

The semiconductor substrate 302 and the semiconductor substrate 702 can be bonded at a bonding interface 712. In aspects, the semiconductor substrate 702 can include a passivation material 714 and a passivation material 716 that implement a bonding surface that bonds with a bonding surface of the semiconductor substrate 302. The passivation material 714 can be disposed at the active area 706, and the passivation material 716 can be disposed at the scribe area 708 and the peripheral area 710. The passivation material 714 can be a same material as the passivation material 314, and the passivation material 716 can be a same material as the passivation material 316. The semiconductor substrate 302 and the semiconductor substrate 702 can be aligned such that the semiconductor dies 304 and the semiconductor dies 704 are aligned. In this way, the passivation material 314 can bond with the passivation material 714 and the passivation material 316 can bond with the passivation material 716 at the bonding interface 712.

The bond can be formed through hybrid or fusion bonding. In aspects, the semiconductor dies 304 and the semiconductor dies 704 can be bonded in a front-to-back arrangement such that the front of the semiconductor dies 304 faces the back of the semiconductor dies 704. The passivation material 316 and the passivation material 716 can include a passivation material with a high bond energy. As a result, it may be difficult to separate the semiconductor substrate 302 and the semiconductor substrate 702 at the bonding interface 712, thereby reducing the occurrence of voids, particularly at the edge of the substrates where the passivation material 316 and the passivation material 716 are present and voids are more likely to occur.

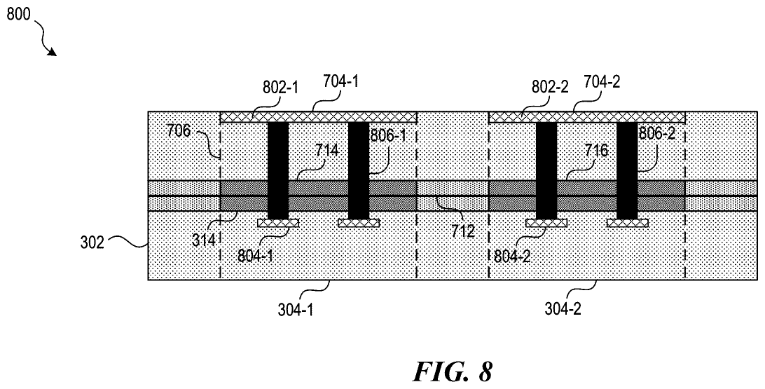

Turning next to FIG. 8, at stage 800, circuitry 802-1 and circuitry 802-2 (referred to collectively as circuitry 802) at the semiconductor dies 704 are respectively coupled with circuitry 804-1 and circuitry 804-2 (referred to collectively as circuitry 804) at the semiconductor dies 304 through respective through-silicon vias (TSVs) 806-1 and TSVs 806-2 (referred to collectively as TSVs 806). The TSVs 806 can provide connectivity to enable the communication of signaling between the semiconductor dies 704 and the semiconductor dies 304. The circuitry 802 and the circuitry 804 can include functional circuitry (e.g., transistors, diodes, capacitors, resistors, etc.) or connective circuitry (e.g., traces, lines, vias, etc.) implemented at the semiconductor dies 704 and the semiconductor dies 304, respectively. The circuitry 802 can be disposed at the semiconductor dies 704 before or after coupling the semiconductor dies 704 with the semiconductor dies 304.

The TSVs 806 can be implemented in a TSV-first, TSV-middle, or TSV-last process. In aspects, the TSVs 806 are implemented in a TSV-last process. For example, the semiconductor dies 704 can be bonded to the semiconductor dies 304, and via holes can be created through the semiconductor substrate 702. The via holes can be created through etching, drilling, or any other processes. The via holes can extend through the semiconductor substrate 702 (e.g., at the active area 706), the passivation material 714, and the passivation material 314. In aspects, the vias holes can extend entirely to a back end of line layer of the semiconductor dies 304 at which the circuitry 804 is disposed. In this way, metal-metal interconnects need not be formed at the bonding interface 712. Conductive material can be disposed within the via holes to implement the TSVs 806. The conductive material can be disposed through dispensing, CVD, PVD, plating, electroless plating, or any other suitable technique. In some cases, passivation material can be disposed at the walls of the via holes to insulate the TSVs 806. In aspects, this passivation material can be the same as the passivation material 714 to maintain consistency, which can improve yield and predictability.

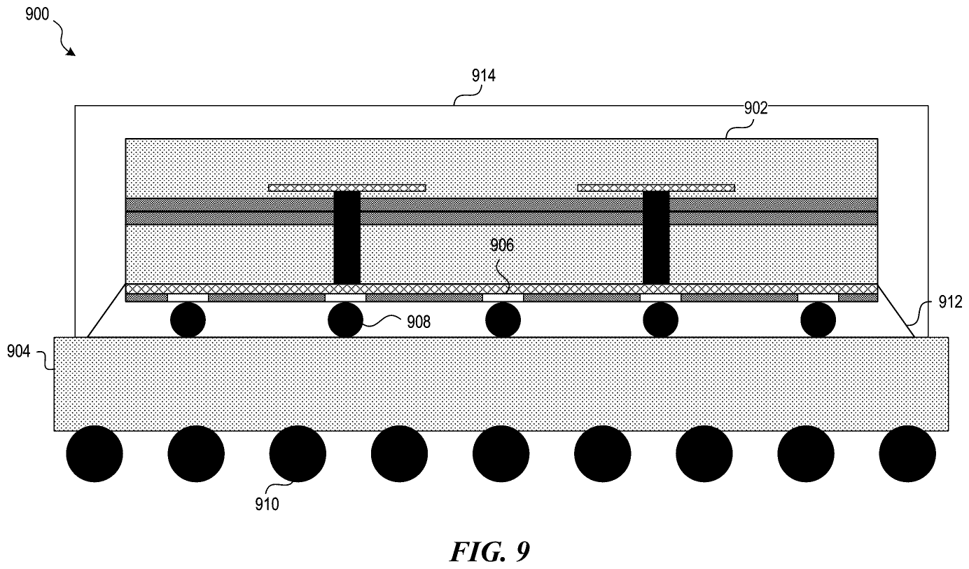

Turning next to FIG. 9 at stage 900, a stack of semiconductor dies 902 are singulated and packaged. The singulated stack of semiconductor dies 902 can include pairs of semiconductor dies corresponding to semiconductor dies coupled with one another (e.g., semiconductor die 304-1 and semiconductor die 704-1 of FIG. 8). The stack of semiconductor dies 902 can be singulated by sawing the substrates between the semiconductor dies at the scribe area.

The stack of semiconductor dies 902 can then be packaged into a semiconductor device. The stack of semiconductor dies 902 is attached to a package-level substrate 904 (e.g., printed circuit board (PCB), interposer, semiconductor substrate, another semiconductor die). The stack of semiconductor dies 902 includes one or more external contact pads 906 coupled through connective circuitry (e.g., traces, lines, vias, and so on) to circuitry at the stack of semiconductor dies 902. Connective structures 908 (e.g., solder, conductive pillars, or the like) can be formed between the contact pads 906 and contacts (not shown) at the package-level substrate 904 to enable electrical signaling to pass between the stack of semiconductor dies 902 and the package-level substrate 904. The package-level substrate 904 can further include package-level contact pads (not shown) that provide external connectivity (e.g., power, ground, and input/output (I/O) signals) through solder balls 910 or other connective structures to the stack of semiconductor dies 902. Traces, lines, vias, and other electrical connection structures in the package-level substrate 904 can electrically connect the package-level contact pads to contact pads at an upper surface of the package-level substrate 904.

An underfill material 912 (e.g., capillary underfill) can be provided between the stack of semiconductor dies 902 and the package-level substrate 904 to provide electrical insulation to the connective structures 908 and structurally support the device. The stack of semiconductor dies 902 and the package-level substrate 904 can be at least partially encapsulated by an encapsulant material 914 (e.g., mold resin compound or the like) to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, additional semiconductor dies in the stack of semiconductor dies, multiple stacks of semiconductor dies, mutatis mutandis. Any additional semiconductor dies or stacks of semiconductor dies could be coupled with other dies in the assembly through similar techniques as described for the stack of semiconductor dies 902.

In accordance with one aspect of the present disclosure, the semiconductor devices illustrated in the assemblies of FIGS. 1-9 could be memory dies, such as DRAM dies, NAND memory dies, NOT-OR (NOR) memory dies, magnetic random-access memory (MRAM) dies, phase change memory (PCM) dies, ferroelectric random-access memory (FeRAM) dies, static random-access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). For example, the semiconductor device can be a 3D NAND or 3D DRAM device. In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby). For example, the semiconductor device can include a logic die with multiple stacks of memory dies (e.g., DRAM, NAND, etc.) coupled therewith.

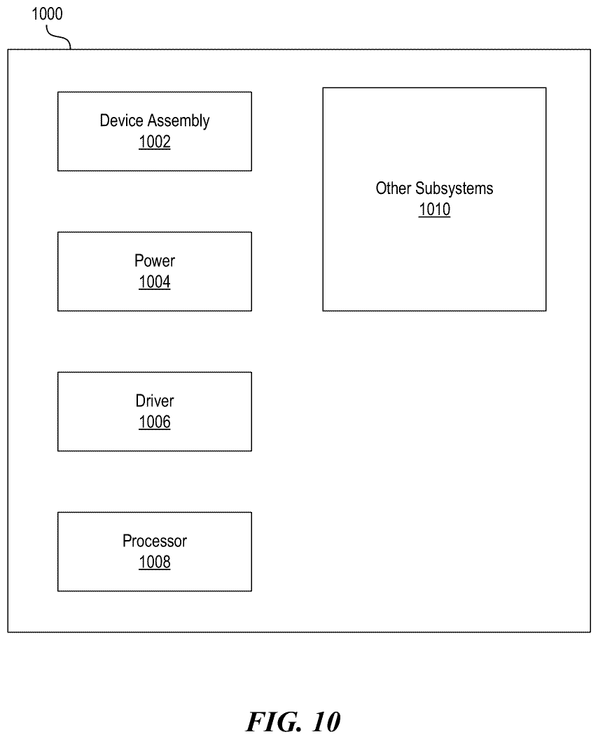

Any one of the semiconductor devices and semiconductor device assemblies described above with reference to FIGS. 1-9 can be incorporated into any of a myriad of larger and/or more complex systems, a representative example of which is system 1000 shown schematically in FIG. 10. The system 1000 can include a semiconductor device assembly 1002 (e.g., a discrete semiconductor device), a power source 1004, a driver 1006, a processor 1008, and/or other subsystems or components 1010. The semiconductor device assembly 1002 can include features generally similar to those of the semiconductor device assemblies described above with reference to FIGS. 1-9. The resulting system 1000 can perform any of a wide variety of functions, such as memory storage, data processing, and/or other suitable functions. Accordingly, the representative system 1000 can include, without limitation, hand-held devices (e.g., mobile phones, tablets, digital readers, and digital audio players), computers, vehicles, appliances, or other products. Components of the system 1000 may be housed in a single unit or distributed over multiple, interconnected units (e.g., through a communications network). The components of the system 1000 can also include remote devices and any of a wide variety of computer-readable media.

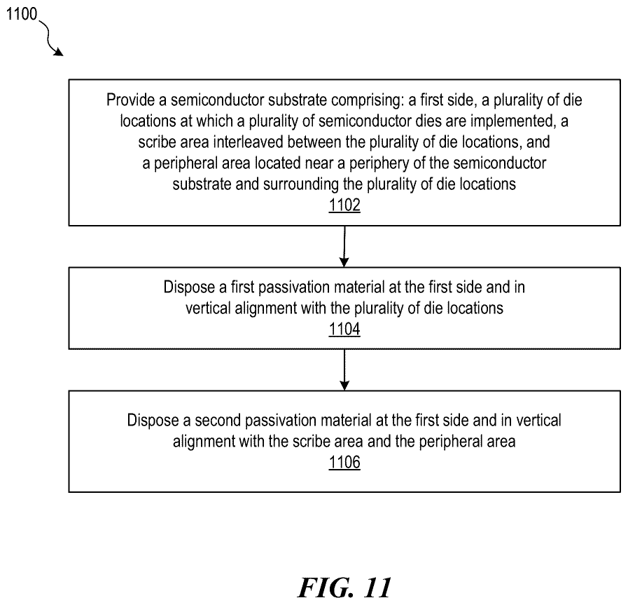

FIG. 11 illustrates a method 1100 for assembling a semiconductor device in accordance with an embodiment of the present technology. Although illustrated in a particular configuration, one or more operations of the method 1100 may be omitted, repeated, or reorganized. Additionally, the method 1100 may include other operations not illustrated in FIG. 11, for example, operations detailed in one or more other methods described herein.

At 1102, a semiconductor substrate is provided. The semiconductor substrate includes a first side, a plurality of die locations at which a plurality of semiconductor dies are implemented, a scribe area interleaved between the plurality of semiconductor dies, and a peripheral area located near a periphery of the semiconductor substrate and surrounding the plurality of die locations. In some cases, the substrate is a semiconductor wafer.

At 1104, a first passivation material is disposed at the first side of the semiconductor substrate in a location that is vertically aligned (e.g., along an axis that is normal to the first side of the semiconductor substrate) with the active area. In some cases, the first passivation material can be disposed only at the plurality of die locations. In other cases, the first passivation material is disposed across the entire first surface and portions of the first passivation material are removed to leave only the portions corresponding to the plurality of die locations. The first passivation material can include an insulative material, such as a dielectric material. In aspects, the first passivation material can include a same dielectric material as used to insulate TSVs through the substrate. For example, the first passivation material can include silicon oxide or silicon oxide carbon. As a result, the TSV formation process and other assembly processes can be more predictable and produce a higher yield.

At 1106, a second passivation material is disposed at the first side in a location that corresponds to the scribe area and the peripheral area. In some cases, the second passivation material can be disposed only at the scribe area and the peripheral. In other cases, the first passivation material is disposed across the exposed portions of the first surface and over the first passivation material. Then, the second passivation material can be thinned to expose the first passivation material and implement a bonding surface having the first passivation material at the plurality of die locations and the second passivation material at the scribe area and the peripheral area. The second passivation material can include an insulative material, such as a dielectric material. In aspects, the second passivation material can have a higher bonding energy than the first passivation material. For example, the second passivation material can include silicon carbon nitride or a HARP dielectric. As a result, bonds between semiconductor substrates using the second passivation material can be more difficult to separate and the occurrence of voids can be limited.

Once the passivation materials are disposed at the semiconductor substrate, the semiconductor substrate can be coupled with an additional semiconductor substrate implementing similar passivation materials as the semiconductor substrate. Coupling the substrates can couple corresponding dies on the substrates. Further, the scribe areas can align when coupled. The substrates can be coupled through the passivation materials, for example, through fusion or hybrid bonding.

Once bonded, the semiconductor substrate and the additional semiconductor substrate can be sawed at the scribe area. Sawing the wafers can singulate individual stacks of semiconductor dies that can be packaged into various electronic devices. In some cases, sawing the semiconductor substrates can remove the scribe areas and the peripheral areas, leaving only the semiconductor dies that have been bonded through the first passivation material. Thus, the techniques disclosed herein can improve reliability in semiconductor bonding processes (e.g., by limiting the occurrence of voids and maintaining consistency in assembly processes) with minimal changes to the resultant semiconductor devices.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using dispensing, CVD, PVD, atomic layer deposition, plating, electroless plating, spin coating, and/or other suitable techniques. Similarly, materials can be removed, for example, using plasma etching, wet etching, CMP, drilling, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a SOI substrate, such as SOG or SOP, or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a semiconductor substrate comprising:
a first surface;
a plurality of die locations at which a plurality of semiconductor dies are implemented;
a scribe area interleaved between the plurality of die locations; and
a peripheral area located near a periphery of the semiconductor substrate, and surrounding the plurality of die locations;
a first passivation material disposed at the first surface and vertically aligned with the plurality of die locations; and
a second passivation material disposed at the first surface and vertically aligned with the scribe and the peripheral area, the second passivation material different from the first passivation material,
wherein the first passivation material and the second passivation material implement a bonding surface of the semiconductor device assembly.

2. The semiconductor device assembly of claim 1, wherein a bond energy of the second passivation material is higher than a bond energy of the first passivation material.

3. The semiconductor device assembly of claim 1, wherein the first passivation material comprises silicon oxide.

4. The semiconductor device assembly of claim 1, wherein the first passivation material comprises silicon oxide carbon.

5. The semiconductor device assembly of claim 1, wherein the second passivation material comprises silicon carbon nitride.

6. The semiconductor device assembly of claim 1, wherein the second passivation material comprises a high aspect ratio process (HARP) dielectric.

7. A method, comprising:
providing a semiconductor substrate comprising: a first side, a plurality of die locations at which a plurality of semiconductor dies are implemented, a scribe area interleaved between the plurality of die locations, and a peripheral area located near a periphery of the semiconductor substrate and surrounding the plurality of die locations;
disposing a first passivation material at the first side and vertically aligned with the plurality of die locations; and
disposing a second passivation material at the first side and vertically aligned with the scribe area and the peripheral area, the second passivation material different from the first passivation material,
wherein the first passivation material and the second passivation material are exposed to implement a bonding surface.

8. The method of claim 7, further comprising planarizing the first passivation material and the second passivation material to expose the first passivation material and the second passivation material at the bonding surface.

9. The method of claim 7, further comprising:
disposing the first passivation material at the first side and in vertical alignment with the plurality of die locations, the scribe area, and the peripheral area; and
removing a portion of the first passivation material vertically aligned with the scribe area and the peripheral area such that the first passivation material is vertically aligned with the plurality of die locations.

10. The method of claim 9, further comprising:
disposing the second passivation material at the first side and over the first passivation material; and
removing a portion of the second passivation material disposed over the first passivation material such that the first passivation material is exposed at the bonding surface and the second passivation material is vertically aligned with the scribe area and the peripheral area.

11. The method of claim 7, further comprising:
providing a second semiconductor substrate comprising: a second side, a second plurality of die locations corresponding to the plurality of die locations, a second scribe area corresponding to the scribe area, and a second peripheral area corresponding to the peripheral area;
disposing a third passivation material at the second side and in vertical alignment with the second plurality of die locations, wherein the third passivation material and the first passivation material are a same material;
disposing a fourth passivation material at the second side and in vertical alignment with the second scribe area and the second peripheral area, wherein the fourth passivation material and the second passivation material are a same material,
wherein the third passivation material and the fourth passivation material are exposed to implement a second bonding surface; and
coupling the semiconductor substrate and the second semiconductor substrate at the bonding surface and the second bonding surface such that the first passivation material couples with the third passivation material and the second passivation material couples with the fourth passivation material.

12. The method of claim 11, wherein:
a back end of line layer of a first semiconductor die of the plurality of semiconductor dies is disposed at the first side; and
the method further comprises:
creating an opening through the second semiconductor substrate, the first passivation material, and the third passivation material to expose the back end of line layer of the first semiconductor die; and
disposing conductive material in the opening to implement a via coupled with the back end of line layer of the first semiconductor die.

13. The method of claim 11, further comprising:
sawing the semiconductor substrate, the second semiconductor substrate, the second passivation material, and the fourth passivation material at the scribe area and the second scribe area to singulate each of the plurality of semiconductor dies.

14. The method of claim 7, wherein a bond energy of the second passivation material is higher than a bond energy of the first passivation material.

15. The method of claim 7, wherein the first passivation material comprises silicon oxide.

16. The method of claim 7, wherein the second passivation material comprises silicon carbon nitride.

17. A semiconductor wafer, comprising:
a first surface;
a plurality of die locations at which a plurality of semiconductor dies are implemented;
a scribe area interleaved between the plurality of die locations;
a peripheral area located near a periphery of the semiconductor wafer and surrounding the plurality of die locations; and
a layer of passivation material disposed at the first surface, the layer of passivation material including a first passivation material vertically aligned with the plurality of die locations and a second passivation material vertically aligned with the scribe area and the peripheral area, the second passivation material different from the first passivation material.

18. The semiconductor wafer of claim 17, wherein a bond energy of the second passivation material is higher than a bond energy of the first passivation material.

19. The semiconductor wafer of claim 17, wherein the first passivation material comprises silicon oxide.

20. The semiconductor wafer of claim 17, wherein the second passivation material comprises silicon carbon nitride.
